(19) United States
(12) Patent Application Publication
(10) Pub. No.: US 2004/0055871 A1
(43) Pub. Date: Mar. 25, 2004

(54) Use of ion beams for protecting substrates from particulate defect contamination in ultra-low-defect coating processes

(75) Inventors: Christopher C. Walton, Berkeley, CA (US); James A. Folta, Livermore, CA (US)

Correspondence Address: Deputy Laboratory Counsel For Intellectual, Property, Lawrence Livermore National Laboratory, P.O. Box 808, L-703, Livermore, CA, 94551, US

(73) Assignee: The Regents of the University of California

(21) Appl. No.: 10/254,119

(22) Filed: Sep. 25, 2002

(51) Int. Cl. C23C 14/32

(52) U.S. Cl. 204/192.11; 204/298.04

(57) ABSTRACT

A method and means are provided for actively protecting a substrate from particulate contamination during thin film deposition. An intense beam of ions or ionized clusters is directed through the space immediately in front of the surface being coated, and the kinetic energy of the ions is used to deflect any approaching particle defects to the side, preventing them from reaching the surface being coated.

The United States Government has rights in this invention pursuant to Contract No. W-7405-ENG-48 between the United States Department of Energy and the University of California for the operation of Lawrence Livermore National Laboratory.

### BACKGROUND OF THE INVENTION

1. Field of the Invention

The present invention relates to low-defect coating processes, and more specifically, it relates to techniques for protecting a substrate from particulate contamination while a thin film is being applied to the substrate.

2. Description of Related Art

A variety of thin film coating processes require ultra-clean coatings with very few particulate defects. Examples include sputtering of metal films as conductors in IC fabrication (where an intruding particle may block coating and cause a gap in a wire line), and coatings for high-fluence mirrors used for laser fusion research. An even more demanding example is multilayer reflective coatings for masks for Extreme Ultraviolet Lithography, where an 81-layer film stack must be deposited at 0.003 defects/cm² over a 6-inch diameter substrate.

In all these coating technologies, a coating source, such as a magnetron, is placed opposite the substrate to be coated. Material emitted by the source moves to the substrate and slowly accumulates there as a thin film. Particles can originate from flakes of coating material accumulating on chamber walls, from uneven erosion or embedded defects in the target material, or even from gas-phase nucleation in the plasma or vapor used for coating. These particles can then be transported to the part being coated by various forces such as electrostatic attraction or mechanical stresses in shields or targets. While careful engineering of the process (such as regular cleaning of chamber walls and use of high-purity target materials) can reduce or delay production of defects by these processes, this process development is expensive and tedious, and it would be preferable to actively protect the part being coated from any defects approaching it. This invention provides a means of such protection that selectively rejects particle defects while admitting atomic species adding to the growing film.

### SUMMARY OF THE INVENTION

It is an object of the present invention to provide a method and means for actively protecting a substrate from particulate contamination while a thin film is being applied to the substrate.

These and other objects will be apparent based on the disclosure herein.

An intense beam of ions or ionized clusters is directed through the space immediately in front of the surface being coated, and the kinetic energy of the ions is used to deflect any approaching particle defects away from the substrate, preventing them from reaching the surface being coated. The invention has a variety of uses, including the production of ultra-low-defect coatings for mirrors for high-fluence lasers. Other uses include ultra-low-defect coatings for advanced lithographic masks and protection of ultra-clean lithographic masks during IC printing; particle interdiction during general coatings for IC production.

### BRIEF DESCRIPTION OF THE DRAWINGS

FIG. 1 shows a low defect deposition tool within an evacuated chamber.

FIG. 2 shows the addition of a second ion beam to the low defect deposition tool of FIG. 1 to protect the mask during coating.

FIG. 3 shows the predicted protection by the invention vs. particle diameter and velocity.

FIG. 4 shows the predicted deflection angle of a 100 nm particle.

FIG. 5 illustrates an experimental set-up to measure the deflection of 1.5 μm and 5 μm SiO₂ spheres.

FIG. 6A illustrates the experimental case where the deflection beam is off.

FIG. 6B shows the experimental case where 1.5 μm spheres are deflected by the beam.

FIG. 6C shows the case for deflection of 5.1 μm spheres.

FIG. 7 is a 2-D surface plot of the deflection angle vs. particle velocity and particle diameter.

FIG. 8 shows predicted and experimental data for the deflection angle for particles traveling at 1 m/s.

### DETAILED DESCRIPTION OF THE PREFERRED EMBODIMENTS

This invention provides a means of active protection of a clean surface being coated by repelling or deflecting approaching particles. In a coating chamber, an intense beam of energetic ions is placed immediately in front of the substrate, directed parallel to the substrate surface. A particle defect approaching the substrate will be hit by this ion beam and struck by a large number of the ions. The impacts push the particle along the direction of the ion beam, and if it is not traveling faster than a critical value it is deflected to the side and does not reach the substrate. Since the defect is larger than the vaporized atoms of coating material which is also approaching the substrate, and the defect is also typically traveling more slowly, it will be struck by more ions per unit of its mass, and will be deflected much more than will the coating material. In this way the technique selectively rejects larger particles but allows the coating material to pass through. Since the ion beam operates under similar conditions to most sputter coating processes, the addition of the ion beam is highly compatible with existing coating technologies, in contrast to other possible protection schemes such as a low-energy gas curtain, which operates at too high a pressure and too low of energies.

Beams of ionized clusters of atoms (“cluster ion beams”) may be used as an alternate means of deflection of particles.

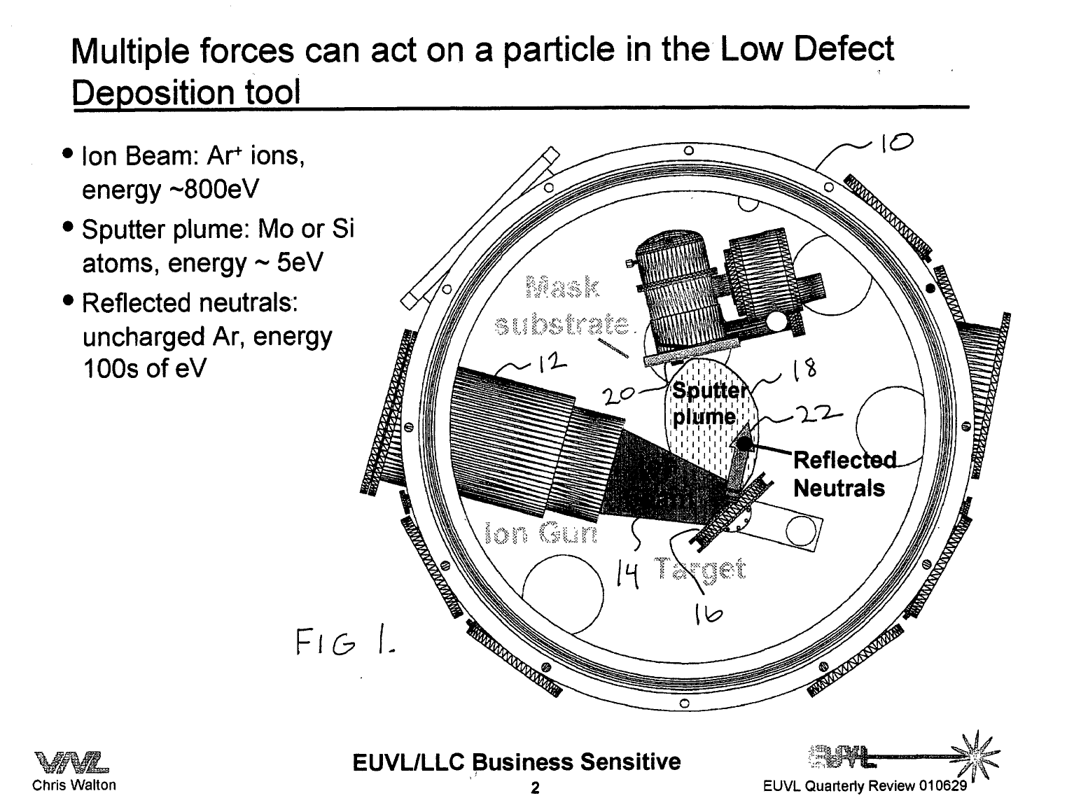

FIG. 1 shows a low defect deposition tool within an evacuated chamber 10. An ion beam gun 12 directs an ion beam 14 onto target 16. A sputter plume 18 is generated and encompasses mask substrate 20. In addition to the sputter plume 18, reflected neutrals 22 of uncharged Ar, and other defect causing particles, may also strike the mask substrate 20. Thus, multiple forces can act on a particle in the Low Defect Deposition tool. The Ar⁺ ion beam may typically comprise ions having energies of about 800 eV. The sputter plume may comprise Mo or Si atoms and have energies of about 5 eV. The reflected neutrals, i.e., uncharged Ar, may have energies of 100s of eV.

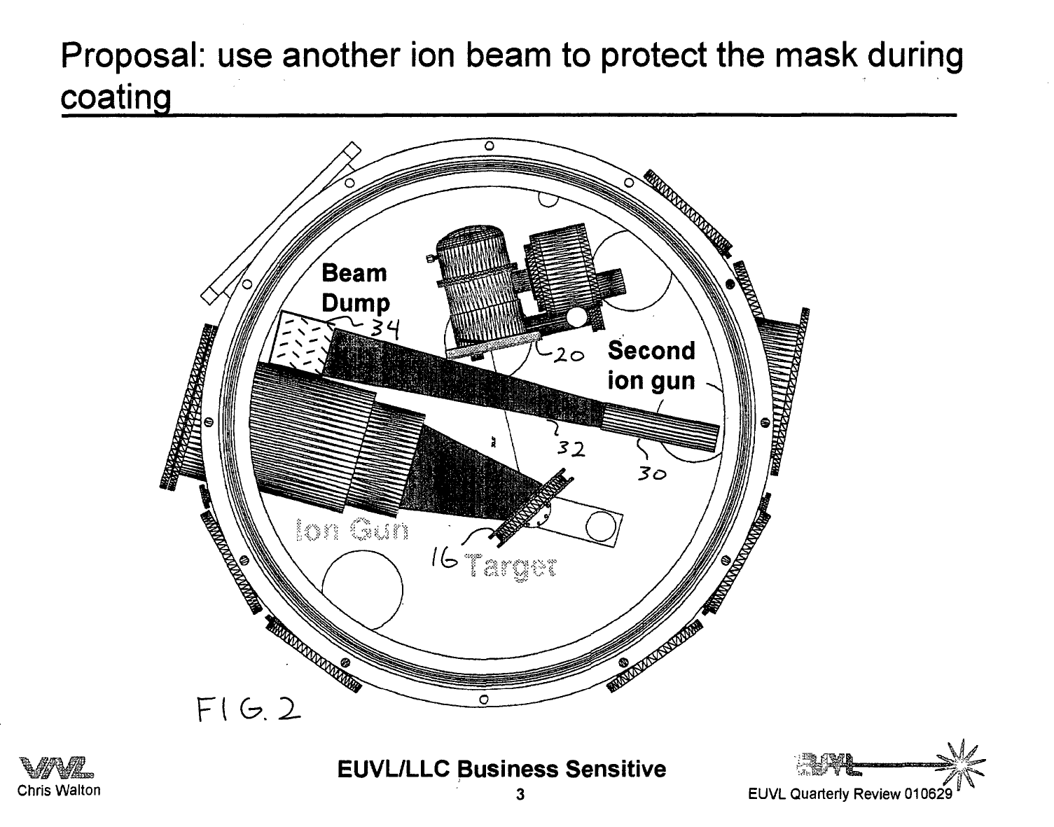

In the present invention, another ion beam is used to protect the mask during coating, as shown in FIG. 2. The low defect deposition tool of FIG. 1 is improved by adding a second ion gun 30, which produces a second ion beam 32 directed between the sputter target 16 and the mask substrate 20. Ion beam 32 is directed onto a beam dump 34.

The dominant force on a particle is expected to be momentum transfer from ions. The angle of deflection is governed by the equation:

$$θ = arctan ( \frac{3 wJ \sqrt{2 {M}_{ion} {E}_{ion}}}{4 ρ {rv}_{perp}^{2}} ) \qquad ( 0.1 )$$

where w is the width of the ion beam, J is the beam current density, Mᵢₒₙ is ion mass, Eᵢₒₙ is the ion energy and ρ is the particle density. Typical values used during reduction to practice are w=0.045 m (small test gun), J=3.6×10⁻³ A/cm², Mᵢₒₙ=6.64×10⁻²⁶ kg (Argon), Eᵢₒₙ=800 eV and ρ=8 g/cm³ (MoSiₓ). The forces expected to act upon the particles include (i) momentum of impacting ions, (ii), electrostatic (small because local |E|˜0) and (iii) gravity (small).

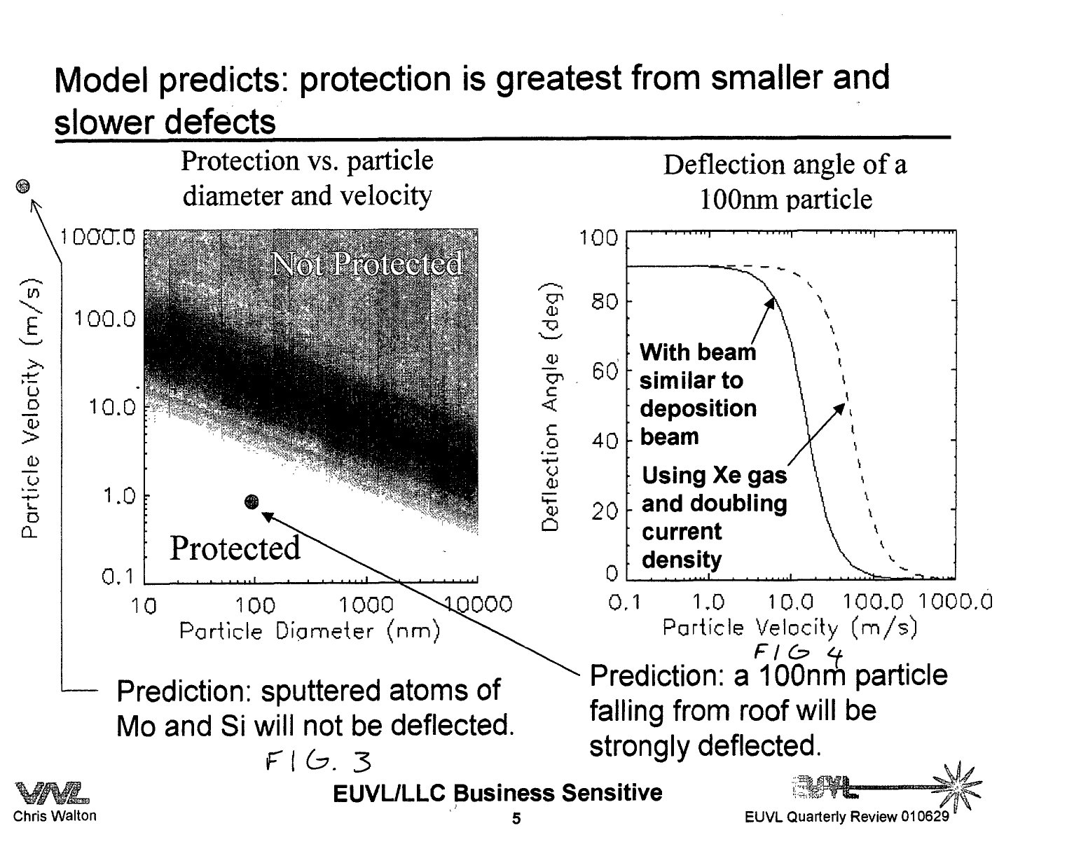

The invention has been modeled using the above equation. The model predicts that protection is greatest from smaller and slower defects. FIG. 3 shows predicted protection vs. particle diameter and velocity. For example, a 100 nm particle falling from the chamber roof will be strongly deflected. However, sputtered atoms of Mo and Si will not be deflected. FIG. 4 shows the predicted deflection angle of a 100 nm particle.

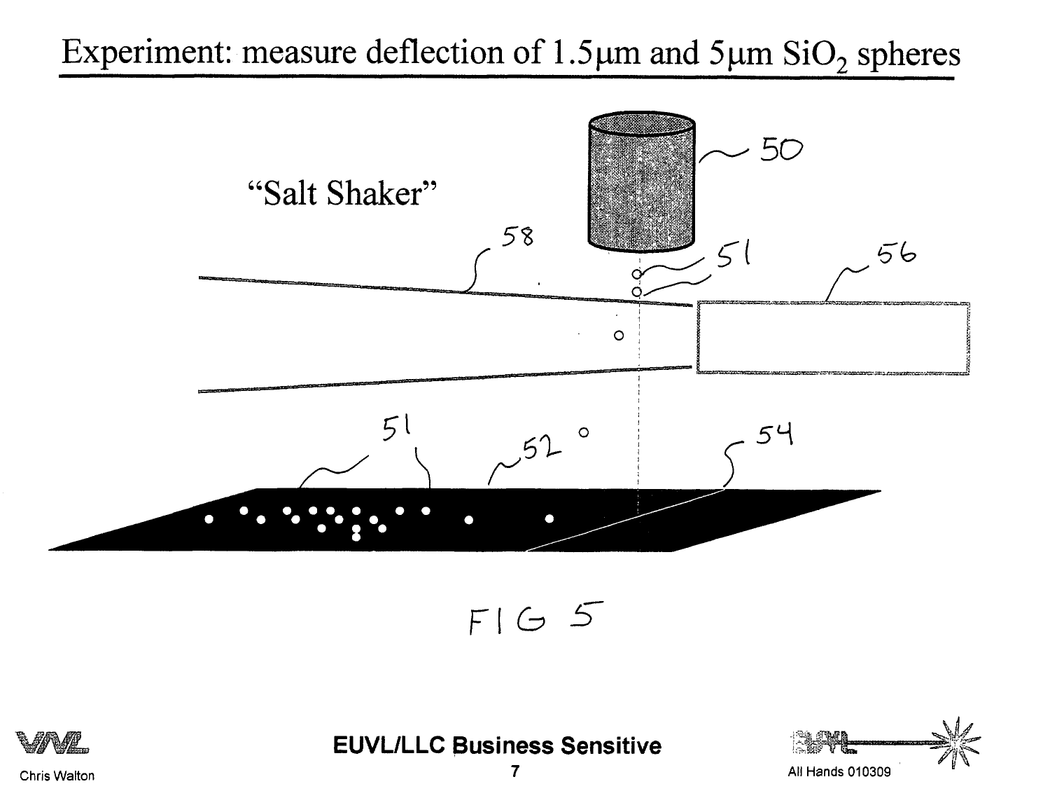

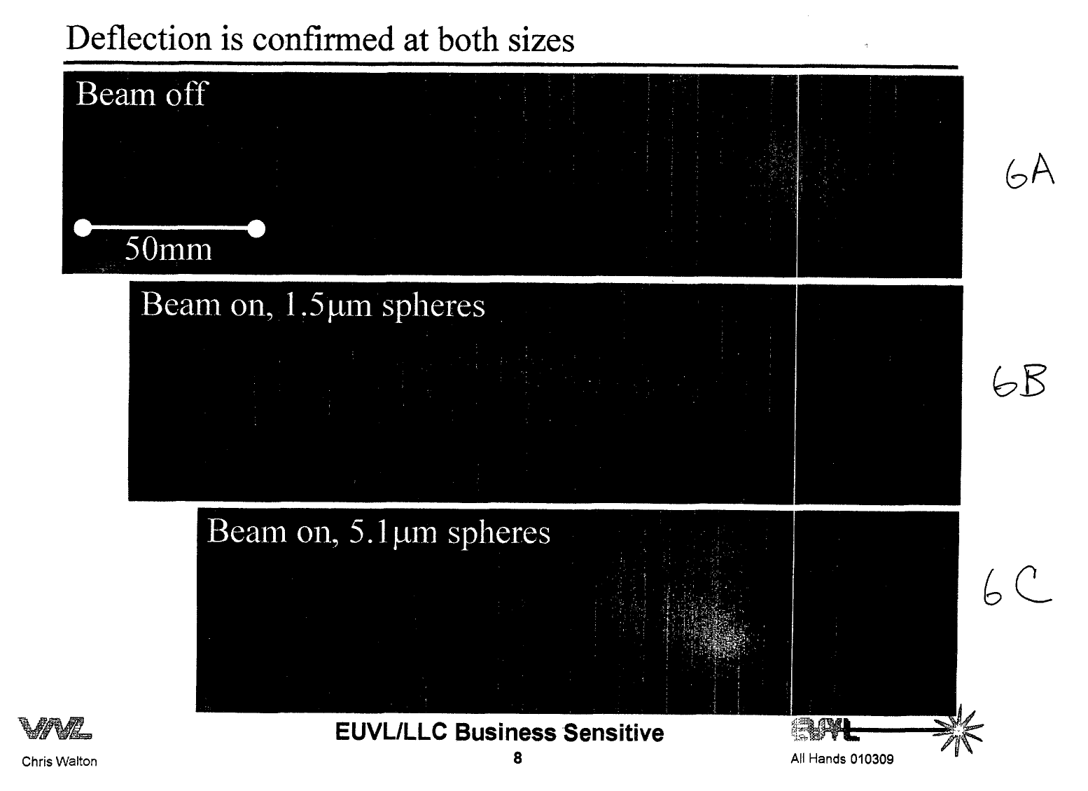

FIG. 5 illustrates an experimental set-up to measure the deflection of 1.5 μm and 5 μm SiO₂ spheres. A shaker 50 was configured to drop SiO₂ spheres 51 onto a collector field 52 at location 54. An ion source 56 provided an ion beam 58 that passed between the shaker 50 and the collector field 52. Referring to FIG. 6A, for the case where the deflection beam 58 is off, particles can be seen to collect around the location 54. FIG. 6B shows the case where 1.5 μm spheres are deflected by the beam. FIG. 6C shows the case for deflection of 5.1 μm spheres. Thus, deflection was confirmed at both sizes.

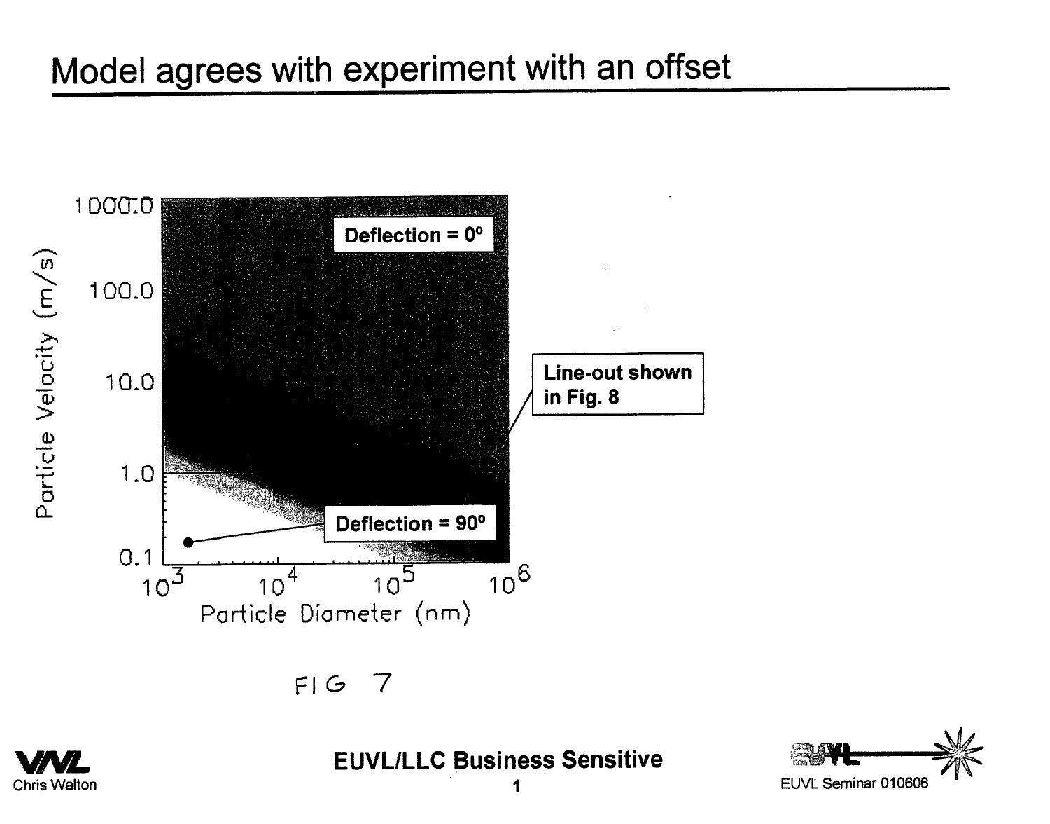

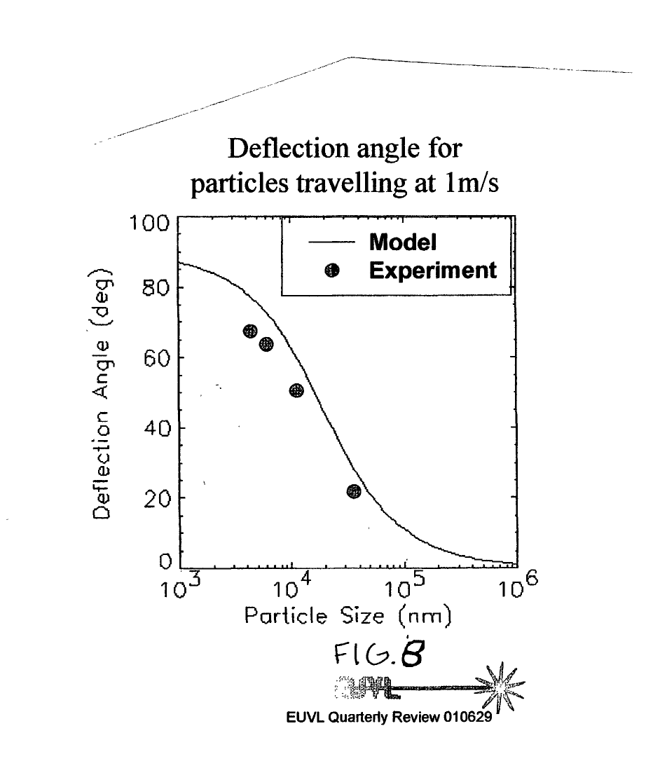

The predicted results agree with experimental results with an offset. Experiments produced particle clusters, which enabled the observation of a range of deflection angles. FIG. 7 is a plot of particle velocity vs. particle diameter. The horizontal line illustrates the velocity at which particle enter the beam under the force of gravity. FIG. 8 shows deflection angle for particles traveling at 1 m/s as predicted by the model and resulting from experiment.

The foregoing description of the invention has been presented for purposes of illustration and description and is not intended to be exhaustive or to limit the invention to the precise form disclosed. Many modifications and variations are possible in light of the above teaching. The embodiments disclosed were meant only to explain the principles of the invention and its practical application to thereby enable others skilled in the art to best use the invention in various embodiments and with various modifications suited to the particular use contemplated. The scope of the invention is to be defined by the following claims.

We claim:

1. A method for actively protecting a substrate from particulate contamination while a thin film is being applied to the substrate, comprising directing an intense beam of ions through the space immediately in front of a surface being coated, wherein the kinetic energy of said ions is used to deflect an approaching particle away from said substrate, preventing it from reaching the surface being coated.

2. The method of claim 1, wherein said substrate is a mirror for high-fluence lasers.

3. The method of claim 1, wherein said substrate comprises a lithographic mask.

4. The method of claim 1, wherein said substrate comprises a silicon wafer.

5. The method of claim 1, wherein said intense beam is directed about parallel to the surface of said substrate.

6. The method of claim 1, wherein said intense beam of ions comprises ionized clusters of atoms.

7. An apparatus for actively protecting a substrate from particulate contamination while a thin film is being applied to the substrate, comprising an ion gun positioned to direct an intense beam of ions through the space immediately in front of a surface being coated, wherein the kinetic energy of ions produced by said ion gun is used to deflect an approaching particle to the side, preventing it from reaching the surface being coated.

8. The apparatus of claim 7, wherein said substrate comprises a silicon wafer.

9. The apparatus of claim 7, wherein said substrate is a mirror for high-fluence lasers.

10. The apparatus of claim 7, wherein said substrate comprises a lithographic mask.

11. The apparatus of claim 7, wherein said ion gun is positioned to direct said intense beam about parallel to the surface of said substrate.

12. The apparatus of claim 7, wherein said ion gun is configured to provide an intense beam of ions comprising ionized clusters of atoms.

13. An improved low defect deposition tool, comprising:
a vacuum chamber;
a first ion gun fixedly attached within said vacuum chamber;
a sputter target fixedly attached within said vacuum chamber in the path of an ion beam produced by said ion gun, wherein said ion beam will produce a sputter plume from said target;
a substrate fixedly attached within said chamber and positioned within the path of said sputter plume; and
a second ion gun fixedly attached within said chamber and positioned to direct a second ion beam between said sputter target and said substrate.

14. The apparatus of claim 13, further comprising a beam dump fixedly attached within said chamber and position within the path of said second ion beam.

15. The apparatus of claim 13, wherein said first beam gun comprises an Ar⁺ ion beam gun.

16. The apparatus of claim 13, wherein said sputter target comprises material selected from the group consisting of Molybdenum and Silicon.
